(19) United States
(12) Patent Application Publication
(10) Pub. No.: US 2012/0060914 A1
(43) Pub. Date: Mar. 15, 2012

(54) COPLANAR TYPE PHOTOVOLTAIC CELL AND METHOD FOR FABRICATING THE SAME

(76) Inventors: KUO-CHIANG HSU, Pingzhen City (TW); KUN-CHIH WANG, Hsinchu City (TW)

(21) Appl. No.: 13/232,284

(22) Filed: Sep. 14, 2011

Related U.S. Application Data
(60) Provisional application No. 61/382,939, filed on Sep. 15, 2010.

(51) Int. Cl. H01L 31/0224; H01L 31/18

(52) U.S. Cl. 136/256; 438/71; 257/E31.13

(57) ABSTRACT

A coplanar type photovoltaic cell and a method for fabricating the same are provided. The coplanar type cell includes: a semiconductor substrate having a front surface and a back surface; and an anode stack and a cathode stack isolated from each other and formed on the back surface of the semiconductor substrate.

### FIELD OF THE INVENTION

The present invention relates to a photovoltaic cell, and more particularly, to a coplanar type photovoltaic cell and a method for fabricating the same.

### BACKGROUND OF THE INVENTION

A solar cell or a photovoltaic cell is a device that converts energy of sunlight into electric energy via a photovoltaic effect. With the global environmental protection trend, solar cells, being hoped to serve as alternative energy, have vigorously developed during the recent years and thus extensively commercialized. Further, buildings, vehicles or other objects may be partially covered by solar cells, which are then able to provide solar energy for powering the buildings, vehicles or objects as much as possible.

The performance of a solar cell is evaluated based on its conversion efficiency, and parameters associated with the conversion efficiency are defined as below:
Voc: open circuit voltage
Isc: short circuit current
Pmp: maximum output power (W)
Vmp: voltage (V) of maximum output power
Imp: current (I) of maximum output power
F.F.: fill factor (%)=(Vmp×Imp/Voc×Isc)×100%

Therefore:

$$\begin{matrix}Pmp = Vmp \times Imp \\ = F . F . \times ( Voc \times Isc ) / 100 \% ; and conversion efficiency ( η ) \\ = maximum output power / incident sunlight power \\ = F . F . \times ( Voc \times Isc ) / ( Pin ) \times 100 \%\end{matrix}$$

From the above definitions, it is deduced that the conversion efficiency of the solar cell is directly proportional to factors including the open circuit voltage (Voc), the short circuit voltage (Voc), and the fill factor (F.F.). That is, the conversion efficiency becomes larger as any value of the three factors increase.

Further, the open circuit voltage Voc of the solar cell is directly proportional to an energy bandgap of a semiconductor electrode material forming the solar cell, meaning that the open circuit voltage of the solar cell gets higher as the energy bandgap of the semiconductor electrode material adopted gets wider. Meanwhile, the open circuit voltage of the solar cell is also affected by the concentration of surface defects and bulk defects of the solar cell. In general, as the surface defect concentration of the solar cell gets larger, the reverse saturation current Io of the solar cell increases and the open circuit voltage Voc decreases. In many low-defect semiconductor materials, a large number of hydrogen atoms are present during the film formation process. The hydrogen atoms passivate the surface defects to significantly reduce the defects concentration, so as to effectively increase both the open circuit voltage Voc as well as the short circuit current Isc.

As previously described, the short circuit current Isc of the solar cell is affected by the concentration of surface defects and bulk defects of the semiconductor electrode material forming the solar cell as well as the energy of effective incident sunlight. As the concentration of surface defects and bulk defects of the semiconductor electrode material gets smaller, the reverse saturation current Io decreases and a ratio of recombination of photon-generated minority carriers is quite low, in a way that the short circuit current Isc is increased. In addition, by increasing the incident sunlight energy that increases the generation of photo current, the short circuit current Isc of the solar cell may also be increased.

The fill factor (F.F.) of the solar cell is determined by characteristics of equivalent serial resistance and equivalent shunt resistance in the solar cell. The fill factor becomes larger as the equivalent serial resistance Rs gets smaller and the equivalent shunt resistance Rsh gets larger. Values of the equivalent serial resistance Rs and the equivalent shunt resistance Rsh are determined by associated material characteristics as well as designs and standards of manufacturing techniques of the solar cell. The equivalent serial resistor Rs is a sum of resistance of all materials and contact resistance of interfaces in a conduction circuit of the solar cell. For example, the resistance in the conduction loop includes: (1) resistance of metal wires; (2) resistance of an N-type semiconductor layer; (3) resistance of a P-type semiconductor layer; (4) contact resistance between metal wires and an N-type semiconductor layer; (5) contact resistance between metal wires and a P-type semiconductor layer; and (6) contact resistance between an N-type semiconductor layer and a P-type semiconductor layer. The equivalent shunt resistance Rsh is chiefly determined by an insulation effect between an N-type semiconductor layer and a P-type semiconductor layer. As a leakage current between N/P semiconductor layers reduces, the equivalent shunt resistance becomes larger and the fill factor F.F. also increases.

A conventional solar cell usually suffers from two drawbacks in a way that the conversion efficiency is restrained. The first drawback is a shading effect of a front electrode. A metal layer or a transparent conductive oxide layer disposed at a front side of the solar cell shields or absorbs incident sunlight to reduce the absorption of the solar cell with respect to incident sunlight energy. Accordingly, photo current is reduced to degrade the conversion efficiency. The second drawback is that, defects of a heavily-doped semiconductor or a metal/semiconductor interface cause recombination of photon-generated minority carriers to further reduce the conversion efficiency.

Therefore, there is a need for a solar cell capable of overcoming the above drawbacks.

### SUMMARY OF THE INVENTION

It is an objective of the present invention to provide a coplanar type photovoltaic cell and a method for fabricating the same for optimizing conversion efficiency via three distinctive features to be described below.

First of all, according to the present invention, an anode stack and a cathode stack are together provided at a back surface of the photovoltaic cell. In a conventional solar cell, metal wires for conduction are densely distributed at a front surface, occupying around 5 to 10% of the front surface area. However, opaque metal wires shield the sunlight from entering N/P semiconductor layers, such that absorption of the solar cell with respect to sunlight energy is reduced to lower the generation of photo current to further degrade conversion efficiency of the solar cell.

According to the present invention, the anode stack and the cathode stack of the solar cell are together provided at the back surface of the solar cell, and conductive metal wires of anode and cathode are also arranged at the back surface of the solar cell. More specifically, the shielding issue that prohibits sunlight from entering N/P semiconductor layers is eliminated. Therefore, the absorption of the solar cell with respect to sunlight is enhanced to increase the generation of photo current to further optimize conversion efficiency.

Secondly, the present invention comprises a design of heterogeneous electrodes. In a conventional solar cell, an N-type semiconductor layer and a P-type semiconductor layer are both formed from a silicon material, and so an open circuit voltage Voc of the solar cell is directly proportional to an energy bandgap of the silicon material.

In the present invention, a bulk of the solar cell is still formed from a silicon material. However, semiconductor materials of anode and cathode of the solar cell are both changed to semiconductor materials having an energy bandgap greater than that of a silicon material. For example, semiconductor materials having a greater energy bandgap include a-Si:H, SiC, GaAs and so on. By introducing materials having a large energy bandgap, a total energy bandgap of the solar cell is so increased to increase an open circuit voltage of the solar cell, thereby optimizing conversion efficiency of the solar cell.

Thirdly, surface defects are passivated in the present invention. During a manufacturing process of a conventional solar cell, an N⁺-type semiconductor layer and a P⁺-type semiconductor layer are formed by doping phosphorous or boron via high-temperature diffusion. However, heavy doping causes defects in crystalline structures formed inside or on a surface of the semiconductor. Since the N⁺-type and P⁺-type semiconductor layers are located in an active layer for absorbing sunlight, the surface defects, if not processed appropriately, develop into critical recombination centers during the powering of the solar cell to degrade the efficiency of the solar cell. Further, metal/semiconductor interfaces that come into contact between the N⁺-type and P⁺-type semiconductor layers and metal electrodes are regions with dense interface defects, which also further compromise the efficiency of the solar cell.

In a conventional solar cell, during transmission of photon-generated minority carriers, photon-generated minority carriers are easily captured by bulk defects, surface defects and interface defects to incur recombination, such that photo current and the open circuit voltage are both reduced such that conversion efficiency is affected to decrease.

According to the present invention, heterogeneous semiconductors with a high energy bandgap are plated onto the bulk of the solar cell to form an anode stack and a cathode stack of the solar cell. The selected high energy bandgap heterogeneous materials are semiconductor materials with low-defect characteristic. Before depositing a heterogeneous semiconductor layer, activated hydrogen atoms are utilized to repair damaged semiconductor surfaces. The benefits of the activated hydrogen atoms are to passivate dangling bonds and surface defects of the semiconductor. Accordingly, the surface defect concentration and the density of recombination centers are reduced, so as to significantly increase an open circuit voltage and at the same time increase the short circuit current, thereby increasing conversion efficiency of the solar cell.

Further, by combining the passivated layer of the heterogeneous semiconductor material with the above-mentioned heterogeneous electrode material having a wide energy bandgap, an electric field caused by potential energy is generated between the silicon bulk and the N⁺-type/P⁺-type semiconductor layers of the solar cell. The electric field isolates the metal/semiconductor high-defect density interface in contact between the N⁺-type/P⁺-type semiconductor layers and the metal electrode from the active region of the solar cell that absorbs sunlight. Therefore, recombination is also reduced to optimize efficiency of the solar cell.

With the distinctive features and structures described above, the present invention discloses a novel solar cell that may be realized on a mono-crystalline or multi-crystalline silicon. Compared to a conventional solar cell, conversion efficiency of the solar cell of the present invention is significantly improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a sectional schematic diagram of a coplanar type photovoltaic cell according to an embodiment of the present invention.

FIGS. 2A to 2G are sectional views of a flow of a method for fabricating a coplanar type photovoltaic cell according to an embodiment of the present invention.

### DETAILED DESCRIPTION OF THE PREFERRED EMBODIMENT

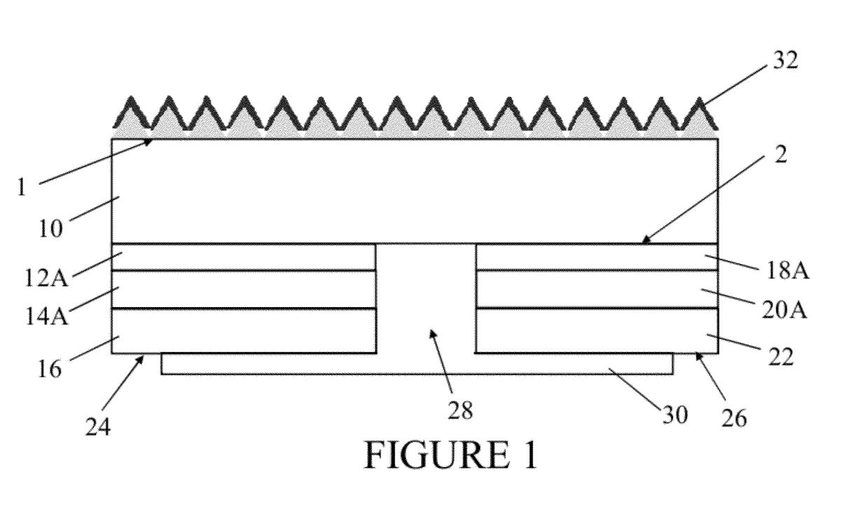

Referring to FIG. 1 showing a sectional schematic diagram of a coplanar type photovoltaic cell according to an embodiment of the present invention. A semiconductor substrate 10 comprises a front surface 1 and a back surface 2. An anode stack 24 and a cathode stack 26 are provided on the back surface 2 of the semiconductor substrate 10, and are isolated from each other via a groove 28. An isolating passivation layer 30 covers portions of the anode stack 24 and the cathode stack 26, and is further filled in the groove 28 to come into contact with the underlying semiconductor substrate 10. Further, the front surface 1 is covered by an anti-reflection layer 32.

The anode stack 24 comprises an anode electrode 16, a P⁺ semiconductor layer 14A and a buffer layer 12A. The cathode stack 26 comprises a cathode electrode 22, an N⁺ semiconductor layer 20A and a buffer layer 18A. The buffer layers 12A and 18A are characterized as low-defect, and are preferably formed by semiconductor materials such as intrinsic a-Si:H, SiC, GaAs and so on. The P⁺ semiconductor layer 14A and the N⁺ semiconductor layer 20A are characterized as having a wide bandgap, and are preferably formed by materials such as a-Si:H, SiC, GaAs and so on. However, the P⁺ semiconductor layer 14A is doped with acceptor type impurities, whereas the N⁺ semiconductor layer 20A is doped with donor type impurities.

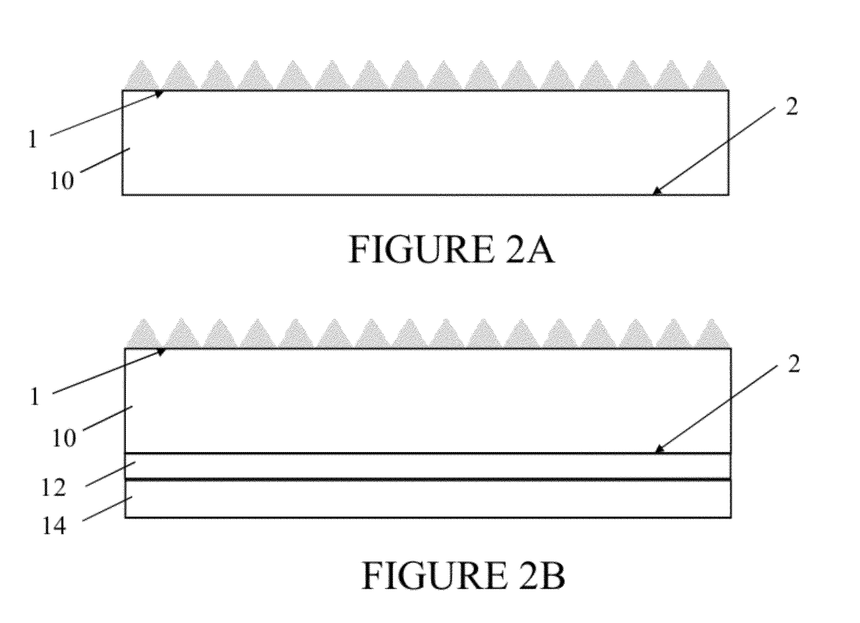

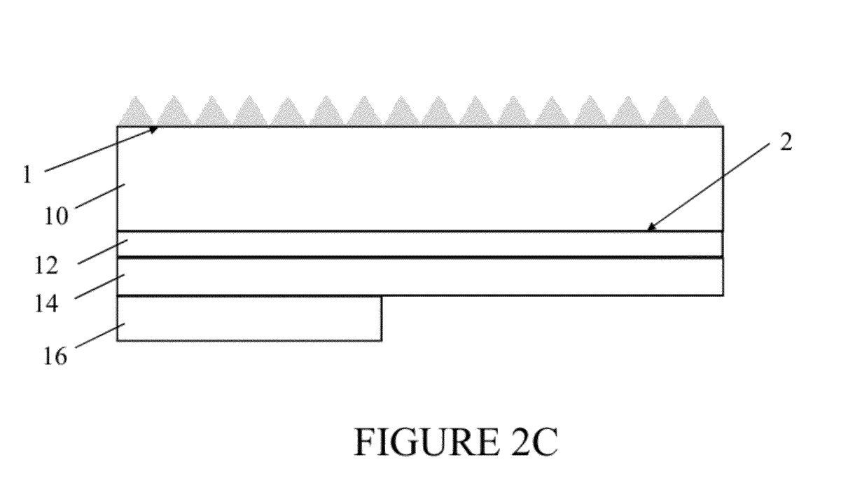

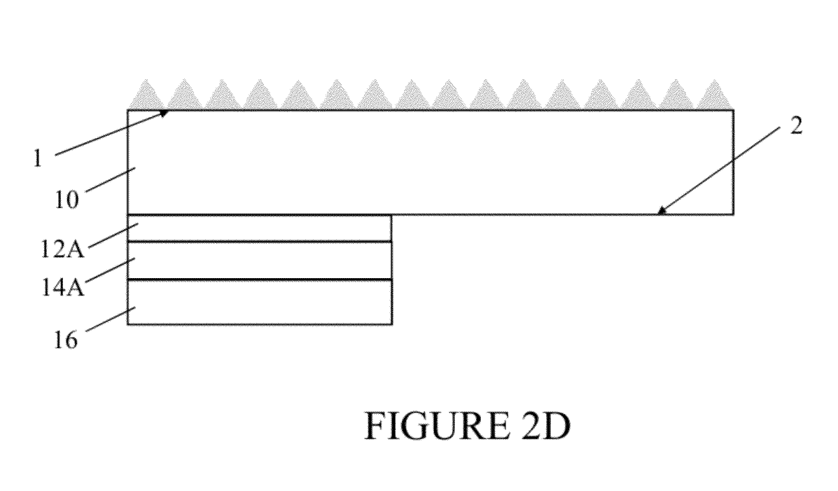

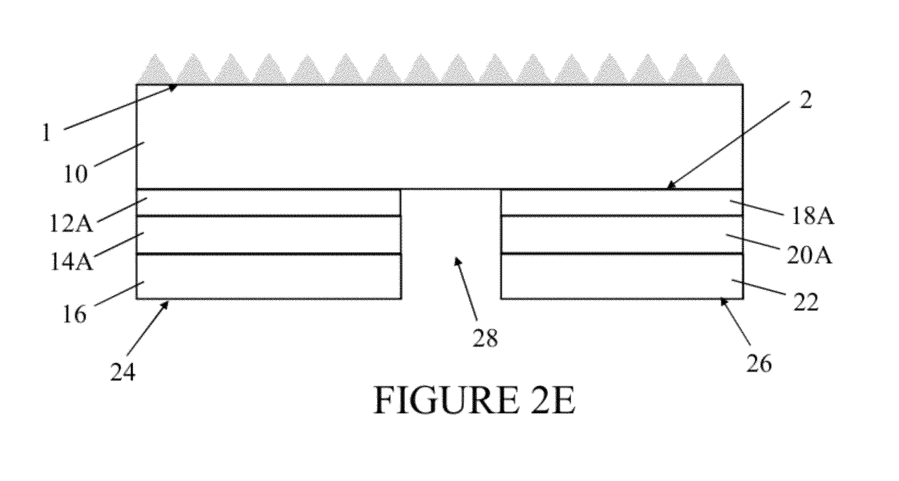

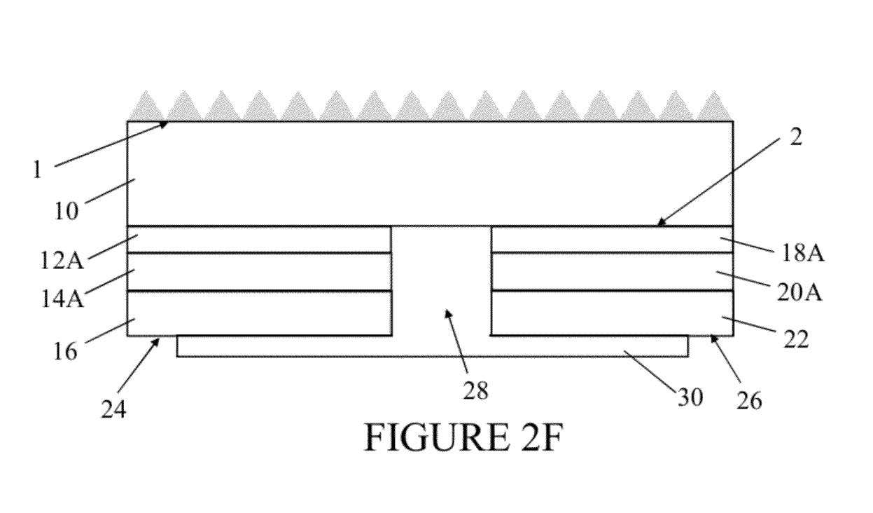

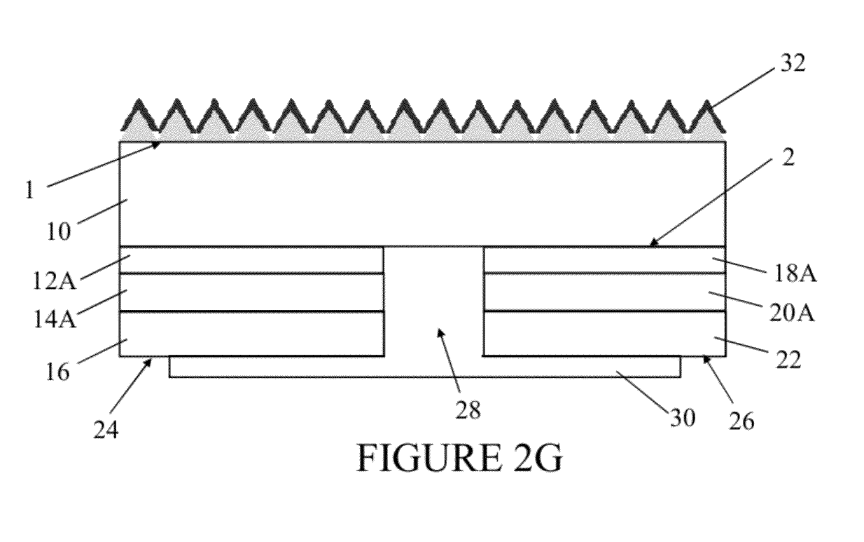

FIGS. 2A to 2G show sectional views of a flow of a method for a fabricating coplanar type photovoltaic cell according to an embodiment of the present invention.

As shown in FIG. 2A, the front surface 10 of the semiconductor substrate 10 is processed into a textured surface. For example, the semiconductor substrate 10 is an N-type or P-type semiconductor wafer, which is formed by mono-crystalline silicon, multi-crystalline silicon, amorphous silicon, SiC, GaAs, etc. For example, acidic or alkaline chemical etching or dry plasma etching is adopted to process the front surface 1 into the textured surface. Thus, the textured front surface 1 allows incident sunlight reflected by an interface for the first time to have a second chance to re-enter the solar cell due to the design of the incident angle, thereby increasing the absorption of effective sunlight.

Referring to FIG. 2B, a buffer layer 12 and a P⁺-type semiconductor layer 14 are sequentially formed on the back surface 2 of the semiconductor substrate 10. Preferably, the buffer layer 12 is formed by semiconductor materials such as intrinsic a-Si:H, SiC, GaAs and so on, and is characterized as being low-defect; the P⁺-type semiconductor layer 14 is formed by materials such as a-Si:H, SiC, GaAs and so on. doped with acceptor impurities, and is characterized as having a wide bandgap.

Next, the anode electrode 16 is formed on the P⁺-type semiconductor layer 14, as shown in FIG. 2C. For example, the approach for forming the anode electrode 16 is first defining a predetermined pattern by mask printing in the semiconductor manufacturing process, followed by metal evaporating or sputtering, and completed by a lift-off step. Alternatively, the anode electrode 16 may be obtained through screen printing of metal paste followed by firing. Preferably, the anode electrode 16 is formed by metal such as Al, Ag, Cu, and so on. By utilizing the anode electrode 16 having the predetermined pattern as a mask, the P⁺-type semiconductor layer 14 and the buffer layer 12 are sequentially defined by plasma etching of the residue to respectively form a P⁺ semiconductor layer 14A and a buffer layer 12A, as shown in FIG. 2D.

A buffer layer 18 and an N⁺-type semiconductor layer 20 are then sequentially formed on the back surface 2 of the semiconductor substrate 10. Preferably, the buffer layer 18 is formed by semiconductor materials such as intrinsic a-Si:H, SiC, GaAs and so on, and is characterized as being low-defect; the N⁺-type semiconductor layer 20 is formed by materials such as a-Si:H, SiC, GaAs and so on and doped with donor type impurities, and is characterized as having a wide bandgap. A cathode electrode 22 is next formed on the N⁺-type semiconductor layer 20. For example, the approach for forming the cathode electrode 22 is first defining a predetermined pattern by mask printing in the semiconductor manufacturing process, followed by metal evaporating or sputtering, and completed by a lift-off step. Alternatively, the cathode electrode 22 may be obtained through screen printing of metal paste followed by firing. Preferably, the cathode electrode 22 is formed by metal such as Al, Ag, Cu, and so on. By utilizing the cathode electrode having the predetermined pattern as a mask, the N⁺-type semiconductor layer 20 and the buffer layer 18 are sequentially defined by plasma etching of the residue to respectively form an N⁺ semiconductor layer 20A and a buffer layer 18A, as shown in FIG. 2E.

Again with reference to FIG. 2E, the anode electrode 16, the P⁺ semiconductor layer 14A and the buffer layer 12A are stacked into the anode stack 24; the cathode electrode 22, the N⁺ semiconductor layer 20A and the buffer layer 18A are stacked into the cathode stack 26. The anode stack 24 and the cathode stack 26 are isolated from each other by the groove 28, through which the semiconductor substrate 10 is partially exposed.

An isolating passivation layer 30 is formed at the side of the back surface of the semiconductor substrate 10. The isolated passivation layer 30 covers portions of the anode stack 24 and the cathode stack 26, and also fills the groove 28 to come into contact with the exposed semiconductor substrate 10, as shown in FIG. 2F. Preferably, the protection layer 30 is obtained through plasma-enhanced chemical vapor deposition (PE-CVD) or sputtering, and may be formed by materials such as SiNₓ, SiOₓ and Ta₂O₅.

An anti-reflection layer 32 is formed to cover the textured front surface 1 of the semiconductor substrate 10. Preferably, the anti-reflection layer 32 is formed by materials such as SiNₓ, SiOₓ and Ta₂O₅. Further, the anti-reflection layer 32 is capable of reducing reflection effects of incident sunlight to increase sunlight re-entering the semiconductor substrate 10.

Therefore, according to the coplanar type photovoltaic cell disclosed by the present invention, the anode stack 24 and the cathode stack 26 are both provided at the back surface 2 of the semiconductor substrate 2 to eliminate shielding effects incurred when electrodes are provided at the front surface 1. Further, in contribution to the layered stack structure of the anode stack 24 comprising the anode electrode 16, the wide bandgap semiconductor layer 14A and the low-defect buffer layer 12A, and the cathode stack 26 comprising the cathode electrode 22, the wide bandgap semiconductor layer 20A and the low-defect buffer layer 18A, conversion efficiency degradation caused by material defects or interface defects are also entirely prevented.

While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. A coplanar type photovoltaic cell, comprising:
a semiconductor substrate, comprising a front surface and a back surface; and
an anode stack and a cathode stack, isolated from each other and provided on the back surface.

2. The coplanar type photovoltaic cell as claimed in claim 1, wherein the anode stack comprises a buffer layer, a P-type semiconductor layer and a metal electrode and the buffer layer is in contact with the semiconductor substrate.

3. The coplanar type photovoltaic cell as claimed in claim 2, wherein the buffer layer has a low-defect characteristic.

4. The coplanar type photovoltaic cell as claimed in claim 2, wherein the P-type semiconductor layer has a wide bandgap characteristic.

5. The coplanar type photovoltaic cell as claimed in claim 1, wherein the cathode stack comprises a buffer layer, an N-type semiconductor layer and a metal electrode and the buffer layer is in contact with the semiconductor substrate.

6. The coplanar type photovoltaic cell as claimed in claim 5, wherein the buffer layer has a low-defect characteristic.

7. The coplanar type photovoltaic cell as claimed in claim 5, wherein the N-type semiconductor layer has a wide bandgap characteristic.

8. The coplanar type photovoltaic cell as claimed in claim 1, wherein the front surface is processed into a textured front surface.

9. The coplanar type photovoltaic cell as claimed in claim 8, further comprising an anti-reflection layer covered on the front surface.

10. The coplanar type photovoltaic cell as claimed in claim 1, further comprising a passivation layer, the passivation layer being provided between the anode stack and the cathode stack and being in contact with a part of the semiconductor substrate.

11. A method for fabricating a coplanar type photovoltaic cell, comprising:
providing a semiconductor substrate, the semiconductor substrate comprising a front surface and a back surface; and
forming an anode stack and a cathode stack on the back surface of the semiconductor substrate.

12. The method as claimed in claim 11, wherein the step of forming the anode stack comprises sequentially forming a low-defect buffer layer, a wide bandgap P-type semiconductor layer, and a metal electrode on the semiconductor substrate.

13. The method as claimed in claim 11, wherein the step of forming the cathode stack comprises sequentially forming a low-defect buffer layer, a wide bandgap N-type semiconductor layer, and a metal electrode on the semiconductor substrate.

14. The method as claimed in claim 11, wherein the front surface is processed into a textured front surface.

15. The method as claimed in claim 14, further comprising forming an anti-reflection layer on the front surface.

16. The method as claimed in claim 11, further comprising forming a passivation layer between the anode stack and the cathode stack, the passivation layer being in contact with a part of the semiconductor substrate.
